(19) United States
(12) Patent Application Publication
(10) Pub. No.: US 2005/0145179 A1
(43) Pub. Date: Jul. 7, 2005

(54) Accessory member for dispensers of alkali metals

(75) Inventors: Lorena Cattaneo, Busto Arsizio (IT); Antonio Bonucci, Milano (IT)

Correspondence Address: AKIN GUMP STRAUSS HAUER & FELD L.L.P., ONE COMMERCE SQUARE, 2005 MARKET STREET, SUITE 2200, PHILADELPHIA, PA, 19103-7013, US

(73) Assignee: SAES GETTERS S.p.A.

(21) Appl. No.: 11/057,829

(22) Filed: Feb. 14, 2005

Related U.S. Application Data
(63) Continuation of application No. PCT/IT03/00524, filed on Aug. 28, 2003.

(30) Foreign Application Priority Data
Sep. 6, 2002 (IT) MI2002A 001904

(51) Int. Cl. C23C 16/00

(52) U.S. Cl. 118/726; 118/504

(57) ABSTRACT

An accessory member for alkali metals dispensers is provided in the form of a screen (30; 40; 60) of substantially tubular shape, one end (34; 44; 64) of which can be applied to an alkali metals dispenser (10). The cross-section of the one end is superposable to an entire alkali metals emission zone (14) of the dispenser (10). The contact portion between the one end (34, 44; 64) and the dispenser (10) is made with a low thermal conductivity material. The screen (30; 40; 60) is provided with an internal surface having a high specific area.

### CROSS-REFERENCE TO RELATED APPLICATIONS

This application is a continuation of International Application No. PCT/IT2003/000524, filed Aug. 28, 2003, which was published in the English language on Mar. 18, 2004, under International Publication No. WO 2004/023508 A2, and the disclosure of which is incorporated herein by reference.

### BACKGROUND OF THE INVENTION

The present invention relates to an accessory member for dispensers of alkali metals.

It is known that alkali metals have been used for a long time in the electronic field. In particular, a field of application of alkali metals is in OLED (Organic Light Emitting Display) screens.

In brief, an OLED is formed of a first planar transparent support (of glass or plastic); a second support, not necessarily transparent, which can be made of glass, metal or plastic, essentially planar and parallel to the first support and fixed along the perimeter thereof, so as to form a closed space; and an active image formation structure inside the space. The active structure is formed of a first series of transparent electrodes, linear and mutually parallel, deposited on the first support; a multilayer of different electroluminescent organic materials, comprising at least one layer of a material conductor of electrons and a layer of a material conductor of electronic vacancies (also defined in the field as “holes”) deposited on the first series of electrodes; and a second series of linear and mutually parallel electrodes that are orthogonally oriented with respect to those of the first series and in contact with the opposite side of the multilayer of organic materials, in such a manner that the latter is comprised between both series of electrodes. For a more detailed explanation of the structure and the operating principles of OLEDs reference is made, for example, to European published patent applications EP 0 845 924 A2 and EP 0 949 696 A2, Japanese published patent application JP9-078058 A and U.S. Pat. No. 6,013,384.

Recently, it has been found that doping one or more of the organic layers of the OLEDs with small quantities of electron-donating materials, in particular cesium, allows reducing the potential difference to be applied to the two series of electrodes for functioning of the screens and therefore the energy consumption of the latter.

For the sake of simplicity, in the present description specific reference will be made to cesium, but it will be understood that the description also applies to other alkali metals which have similar applications.

The doping is carried out by exposing the organic layers of the OLED to cesium vapors in a closed chamber which is maintained under vacuum, in order to avoid the organic layers and, above all, the second series of electrodes (generally made with metals such as barium) being damaged by noxious atmospheric agents and, in particular, by water vapor.

The evaporation of cesium inside the production chamber of the OLED is carried out by using suitable dispensers containing a cesium compound stable to air at room temperature. As a matter of fact, due to its high reactivity toward atmospheric gases and to moisture, cesium is not normally used in the industry as a pure metal. Among the stable cesium compounds, cesium chromate or dichromate can be mentioned which, in mixture which a reducing agent, release cesium as a vapor by heating at temperatures higher than 500° C. Aluminum, silicon or getter alloys, (i.e., alloys based on titanium or zirconium with aluminum or one or more transition elements) are generally used as reducing agents. The use of these mixtures is described for example in U.S. Pat. No. 2,117,735.

Further, cesium dispensers particularly suitable for the production of OLEDs are known from the International patent application publication WO 02/093664. The cesium dispensers comprise a container permeable to cesium vapors and containing a mixture of a reducing agent and a cesium compound selected among molibdate, tungstate, niobate, tantalate, silicate and zirconate. These compounds are more advantageous than the previously described ones, as they do not contain hexavalent chromium, which can cause irritation by contact, swallowing or inhalation and can be carcinogenic in case of long exposures.

In any case, the dispensers for cesium release are essentially formed of a metal container, heatable by Joule effect, capable of retaining solid particles of the cesium compound. At least one part of the dispenser surface is permeable to cesium vapors or provided with small holes or slits through which cesium is emitted in vapor form. Different shapes of dispensers are the subject, for example, of U.S. Pat. Nos. 3,578,834; 3,579,459; 3,598,384; 3,636,302; 3,663,121; and 4,233,936.

The dispensers are positioned inside a chamber for the production of OLEDs, generally on the bottom thereof, whereas on the ceiling thereof is positioned the substrate on which cesium is to be deposited.

However, a remarkable drawback of the known cesium dispensers consists in that metal evaporation leads to the deposition of cesium not only on the organic layers of the OLED, but on the whole internal surface of the chamber.

Since cesium, as any alkali metal, reacts exothermally with air moisture producing molecular hydrogen, it is desirable to avoid the accumulation of large amounts of metal on the chamber walls which could cause deflagrations at the moment of opening the chamber itself.

For this reason, it is necessary to periodically clean the chamber, by passivating the deposited cesium and by removing the same before a large quantity thereof is accumulated. However, this implies the need to frequently stop the manufacturing process in order to open the chamber, carry out these cleaning steps and, before starting the process again, reestablish the vacuum or the inert atmosphere inside the chamber, while at the same time carrying out also a baking operation, in order to eliminate the traces of moisture which, as explained above, may damage the organic layers of the OLED. Obviously, this implies the need of frequent and long maintenance stops, which are disadvantageous from the point of view of process economy.

### BRIEF SUMMARY OF THE INVENTION

Therefore, an object of the present invention is to provide an accessory member for dispensers of cesium and other alkali metals, which solves the above mentioned drawbacks, comprising a screen that allows the capture of excess cesium vapors, thus preventing the deposit of the cesium on the internal walls of the evaporation chamber, while ensuring a constant and uniform deposit yield on the substrate. The object is achieved by an alkali metal vapor screen of essentially tubular shape, for capturing alkali metal vapors, characterized in that it is adapted to be applied with an end thereof to an alkali metals dispenser, the contact portion between the end and the dispenser being made of a low thermal conductivity material, the cross-section of the end being superposable on a whole alkali metals emission zone of the dispenser, the screen being provided with an internal surface having a high specific area.

A first advantage of such a screen is that it can be removed from the inside of the evaporation chamber in a short time and replaced, thus avoiding excessively long maintenance stops.

Another advantage of the screen according to a particular embodiment of the invention is that it can be used even when the substrate on which the metal is to be deposited in the evaporation chamber is not positioned in front of the cesium dispenser.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a perspective view of an example of a known cesium dispenser;

FIG. 2 is a sectional view along line 1′-11′ of the dispenser of FIG. 1;

FIG. 3 is a perspective view of a screen according to a first embodiment of the invention;

FIG. 4 is a perspective view of a screen according to a second embodiment of the invention;

FIG. 5 is a cross-sectional view along line V-V′ of the screen of FIG. 4; and

FIG. 6 is a perspective view of a screen according to a third embodiment of the invention.

### DETAILED DESCRIPTION OF THE INVENTION

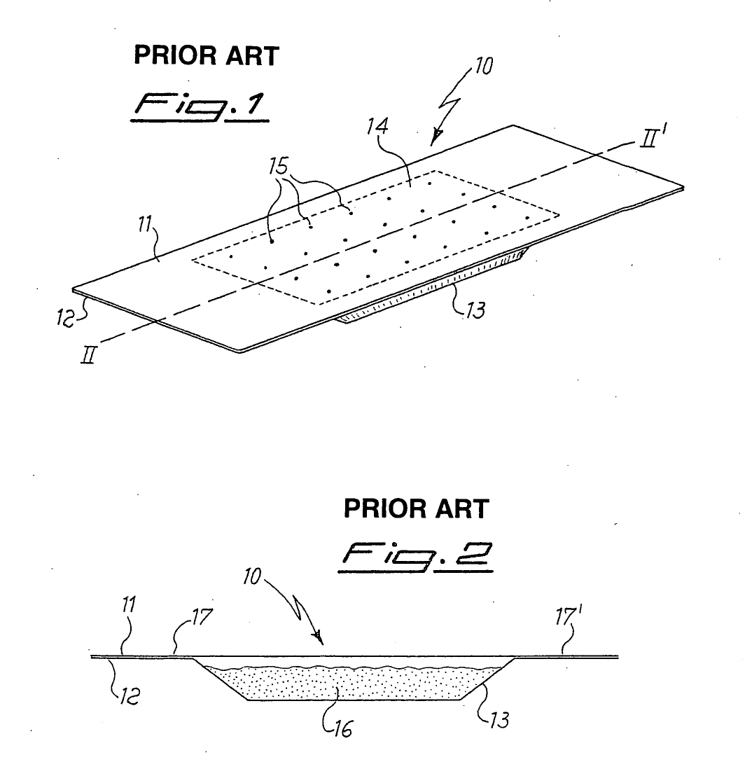

A known cesium dispenser useable with the screen according to the present invention is shown in FIGS. 1 and 2 in perspective and sectional views, respectively. In particular, FIG. 2 shows a view of the dispenser sectioned along line II-II′ of FIG. 1. Dispenser 10 is formed of two metal sheets 11 and 12. In the central portion of sheet 12 is provided a cavity 13 obtained, for example, by cold molding of sheet 12. Sheet 11 is provided in the central portion 14 (marked by the dotted line in FIG. 1) with a series of small holes 15. In the following, portion 14 will be referred to as the alkali metals emission zone. In the assembled dispenser the emission zone 14 corresponds with cavity 13. A mixture 16, suitable for releasing an alkali metal by heating, is contained in cavity 13. The mixture generally comprises a stable compound of an alkali metal and a reducing agent. Sheets 11 and 12 are fixed to each other, externally to cavity 13, so as to guarantee the tightness for the powders. Dispenser 10 is finally provided with two lateral extensions 17 and 17′ useful for the movement by mechanical means in a production line and for connection to electric terminals for heating thereof.

The above shown dispenser 10 is only one example of the alkali metals dispensers which can be used with the accessory member according to the present invention. In other embodiments of the invention the shape of the container and in particular that of the emission zone can be different from the one which is shown here. For example, the emission zone can have a circular shape instead of a rectangular one. Alternatively, the dispenser can be formed of a container having an elongated structure and trapezoidal cross-section, with a longitudinal slit closed by a metal wire which allows cesium evaporation but prevents the powder mixture from coming out. Containers of various shapes and materials are known from the previously cited U.S. patents, and are also commercially available, for example from the Austrian company Plansee AG or from the U.S. company Midwest Tungsten Service, Inc.

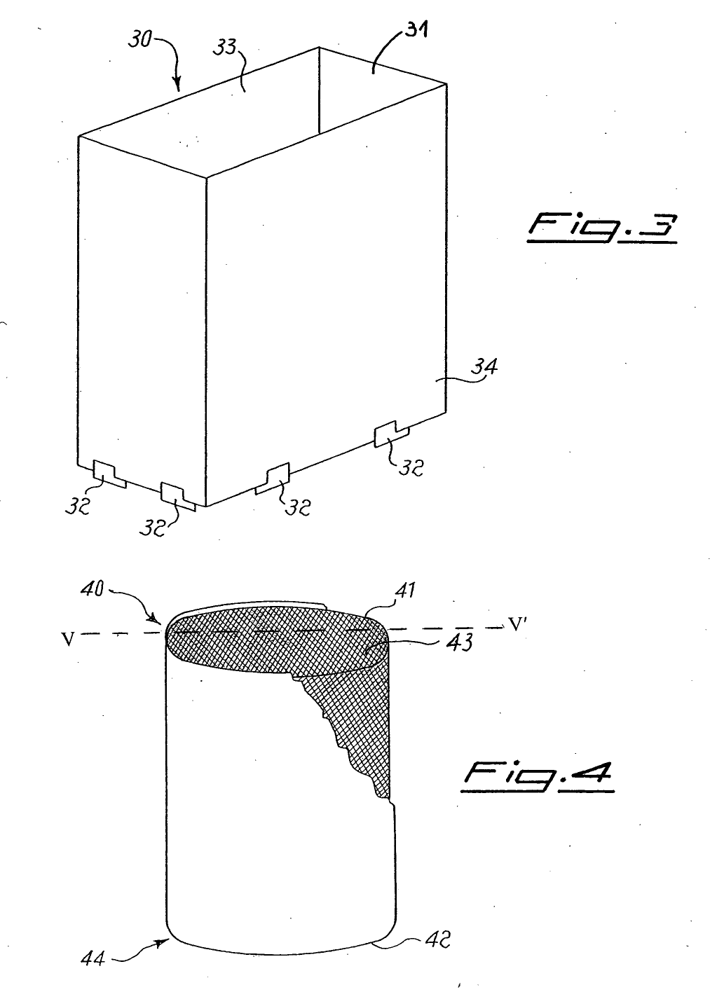

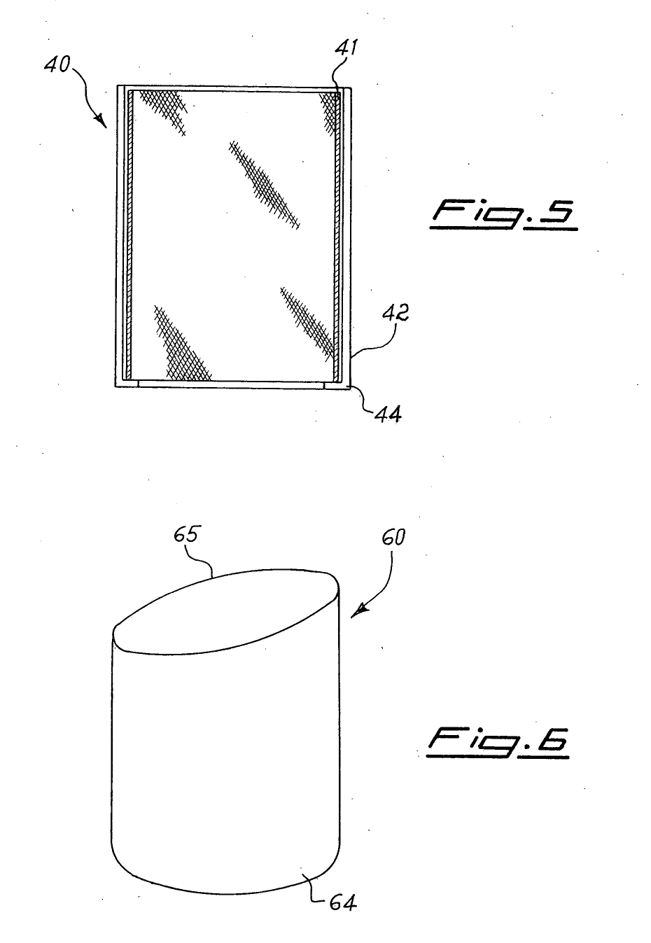

With reference to FIG. 3, there is shown a screen 30 according to the present invention that has a substantially tubular shape and defines an internal cavity 33.

The cross-section of the screen can be rectangular, circular or have any other shape, in such a way that it can be applied with an end 34 thereof on an alkali metals dispenser. In particular, the cross-section of the end must be superposable to the whole emission zone of the dispenser, so that the vapors of the alkali metal generated by the dispenser are completely conveyed into the internal cavity of the screen.

Screen 30 according to the present embodiment of the invention has, in particular, a rectangular cross-section.

The screen according to the present invention must be provided with an internal surface of high specific area. In the present description and claims, the expression “specific area” is intended to mean the ratio between the effective contact area of the surface-with the external environment and the geometric area thereof.

In order to have a high specific area, the internal surface 31 of the screen according to the present invention must have porosities, rugosity or reliefs suitable for capturing excess alkali metal vapors, thus preventing these from depositing on the walls of the evaporation chamber.

A further feature of the screen according to the present invention, which allows capturing the alkali metal vapors, consists in that the portion of contact between the end of the screen and the dispenser must be made of a material having low thermal conductivity. In this way, it is possible to avoid the screen becoming hot due to contact with the alkali metals dispenser, thus causing the re-evaporation of the alkali metals deposited on the internal surface thereof.

For this purpose, screen 30 can be made completely of a low thermal conductivity material, for example of ceramic.

Alternatively, screen 30 can be made of any material and can comprise spacers 32 made of ceramic or another material having a low thermal conductivity. These spacers may be removable.

Further, since another contribution to the heating of the screen is given by radiation, the screen can be made of a material which minimizes the effect. For this reason, it is preferably made of a white material.

Another alternative embodiment of the invention is shown in FIGS. 4 and 5. In these figures, there is shown a screen 40 according to the present invention that has a circular cross-section, and is therefore particularly suitable for being applied around an emission zone of corresponding shape. The screen 40 comprises a tubular member 41 made of close-mesh metallic material and an external casing 42 made of a material having a low thermal conductivity, for example ceramic.

In this case, the mesh tubular member 41 is provided with an internal surface 43 having a high specific area and allows capture of the excess alkali metal vapors, which are emitted by the metal dispenser. The external casing 42 ensures the lateral tightness of the screen, thus preventing those vapors which could pass through the meshes of the tubular member from coming out.

Further, as shown in the cross section of FIG. 5, the external casing 42 of screen 40 acts also as a support for the tubular member 41, thus avoiding direct contact between the alkali metals dispenser and end 44 of the tubular member, and consequent heating of the latter.

The various embodiments of the invention described above can be used by positioning the alkali metal dispenser, with the screen applied thereto, on the bottom of the evaporation chamber, and by positioning the substrate, on which the metal is to be evaporated, on the ceiling of the chamber, exactly above the dispenser.

In contrast, a further embodiment of the invention, shown in FIG. 6, is particularly suitable when the substrate, on which the metal is to be evaporated, is not positioned exactly above the metal dispenser, but is displaced with respect to this.

As a matter of fact, in this case it is necessary that the screen according to the present invention intercept the flow of the alkali metal vapors directed toward the chamber walls, without influencing the part of the vapors directed toward the substrate. The final effect is therefore a net flow directed towards the substrate.

Screen 60 shown in FIG. 6 is provided with an opening which is oblique or slanting with respect to the axis thereof. The opening is the one positioned at its end 65, opposite from end 64 for application on the dispenser, and its obliquity allows obtaining a flow of metal vapors having the desired direction. As a matter of fact, it has been found that positioning screen 60 with its higher side farther from the substrate on which the deposit is to be carried out, it is possible to maintain the efficiency of the metal deposit on the substrate unchanged, while reducing the quantity of cesium deposited on the walls.

The screen according to the present invention can be simply laid on the alkali metals dispenser, or it can be provided with means for fixing it to the dispenser, for example ceramic hooks.

Alternatively, a seat can be provided on the alkali metals dispenser for application of a screen according to the invention. The seat can be formed, for example, of a recess having a shape coincident with that of the lower end of the screen, positioned around its alkali metals emission zone.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. An alkali metal vapor screen for capturing alkali metal vapors, the screen comprising an essentially tubular-shaped body (30; 40; 60) having a first end (34; 44; 64) thereof adapted to be applied to an alkali metals dispenser (10) having an alkali metals emission zone (14), wherein a portion of the first end for contact with the dispenser comprises a low thermal conductivity material, a cross-section of the first end is superposable to the entire alkali metals emission zone (14), and an internal surface (31; 43) of the screen has a high specific area.

2. The screen according to claim 1, comprising a white material.

3. The screen according to claim 1, wherein the contact portion comprises at least one spacer (32).

4. The screen according to claim 3, wherein the at least one spacer comprises ceramic.

5. The screen according to claim 3, wherein the at least one spacer is removable.

6. The screen according to claim 1, wherein the body comprises a tubular member (41) made of a close-mesh metallic material and an external casing (42).

7. The screen according to claim 6, wherein the external casing comprises ceramic.

8. The screen according to claim 1, wherein the body has a circular cross-section.

9. The screen according to claim 1, wherein the body has an opening at a second end (65) thereof opposite to the first end (64), the opening being substantially oblique or slanting with respect to a longitudinal axis of the body.

10. The screen according to claim 1, further comprising means for fixing the body to the alkali metals dispenser.

11. The screen according to claim 1, wherein the first end (34; 44; 64) has a cross-section corresponding to that of a seat provided around the alkali metals emission zone of the dispenser.

12. An alkali metals dispenser for dispensing alkali metal vapors, the dispenser comprising a container (13) holding a stable alkali metal compound from which alkali metal vapors can be released, the container (13) having an alkali metals emission zone (14) in a surface thereof, the emission zone (14) being permeable to alkali metal vapors, and a vapor screen for capturing alkali metal vapors, the screen comprising an essentially tubular-shaped body (30; 40; 60) having a first end (34; 44; 64) thereof contacting the dispenser at the emission zone (14), wherein a portion of the first end contacting the dispenser comprises a low thermal conductivity material, a cross-section of the first end is superposable to the entire emission zone (14), and an internal surface (31; 43) of the screen has a high specific area.

13. The dispenser according to claim 12, wherein the screen comprises a white material.

14. The dispenser according to claim 12, wherein the contact portion comprises at least one spacer (32).

15. The dispenser according to claim 14, wherein the at least one spacer comprises ceramic.

16. The dispenser according to claim 14, wherein the at least one spacer is removable.

17. The dispenser according to claim 12, wherein the body comprises a tubular member (41) made of a close-mesh metallic material and an external casing (42).

18. The dispenser according to claim 17, wherein the external casing comprises ceramic.

19. The dispenser according to claim 12, wherein the body has a circular cross-section.

20. The dispenser according to claim 12, wherein the body has an opening at a second end (65) thereof opposite to the first end (64) the opening being substantially oblique or slanting with respect to a longitudinal axis of the body.
